(19) United States
(12) Patent Application Publication
(10) Pub. No.: US 2008/0203360 A1
(43) Pub. Date: Aug. 28, 2008

(54) Electroluminescent Materials Comprised with Mixture and Display Device Containing the Same

(75) Inventors: So-young Jung, Seoul (KR); Kyu-sung Cho, Kyeongki-do (KR); Kyung-hoon Choi, Seoul (KR); Bong-ok Kim, Seoul (KR); Sung-min Kim, Seoul (KR); Seung-soo Yoon, Seoul (KR)

Correspondence Address: THE WEBB LAW FIRM, P.C., 700 KOPPERS BUILDING, 436 SEVENTH AVENUE, PITTSBURGH, PA, 15219, US

(73) Assignee: GRACEL DISPLAY INC., Seoul (KR)

(21) Appl. No.: 11/814,891

(22) PCT Filed: Jan. 18, 2006
(86) PCT No.: PCT/KR06/00187

§ 371 Date: Jul. 26, 2007

(30) Foreign Application Priority Data
Jan. 27, 2005 (KR) 10-2005-0007350

(51) Int. Cl. C09K 11/06

(52) U.S. Cl. 252/301.16

(57) ABSTRACT

The present invention relates to an electroluminescent material, a process for preparing the same, and a display device containing the same. The electroluminescent compound comprised of the mixture according to the present invention, having high luminescent properties, can be advantageously and easily prepared with high yield.

### FIELD OF THE INVENTION

The present invention relates to an electroluminescent material comprised of a mixture, a process for preparing the same, and a display device containing an electroluminescent material comprised of the mixture.

### BACKGROUND OF THE ART

Among display devices, electroluminescence (EL) devices, being self-luminous type display devices, have advantages of wide visual angle, excellent contrast as well as rapid response rate.

Meanwhile, Eastman Kodak firstly developed an organic EL device employing low molecular aromatic diamine and aluminum complex as a substance for forming a light emitting layer, in 1987 [Appl. Phys. Lett. 51, 913, 1987].

The most important factor to determine luminous efficiency in an organic EL device is light emitting material. Though fluorescent materials have been widely used up to the present as the light emitting material, development of phosphor material, from the aspect of the mechanism of electroluminescence, is one of the best ways to improve the luminous efficiency up to 4 folds, theoretically.

Up to the present, iridium (III) complexes have been widely known as phosphorescent light emitting material: (acac)Ir(btp)₂, Ir(ppy)₃ and Firpic or the like having been known as RGB, respectively [Baldo et al., Appl. Phys. Lett., Vol 75, No. 1, 4, 1999; WO 00/70 655; WO 02/7 492; Korean Patent Laid-Open No. 2004-14346]. Various phosphors have been researched in Japan, Europe and America, in particular.

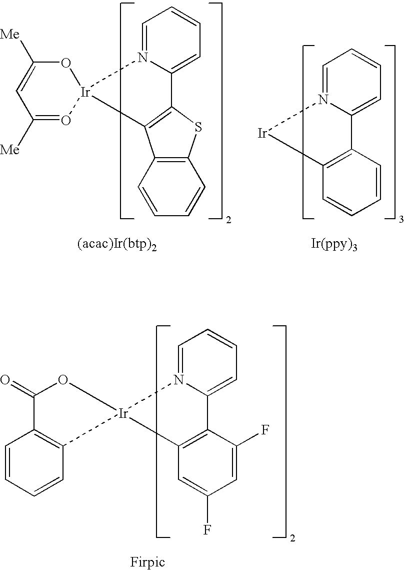

Among the conventional phosphors, there is an iridium complex of 1-phenylisoquinoline, which has been known as having very excellent EL property to exhibit color purity of deep red and high luminous efficiency (reference: A. Tsuboyama, et al., J. Am. Chem. Soc., 2003, 125(42), 12971-12979].

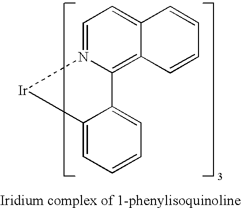

Further, in case of red substance, there is no serious problem in terms of lifetime, so that it tends to be ready to common use if it has excellent color purity or luminous efficiency. Thus, the iridium complex mentioned above is a substance having very high possibility of common use, due to its excellent color purity and luminous efficiency. Since sublimation temperature of the 1-phenylisoquinoline iridium complex is very high, it is disadvantageous in that a process at high temperature higher by 60° C. or more than that in case of the widely known green phosphors is required. Such an application of a high temperature process provides a lasting high temperature environment to the organic material during the process for preparing a display in practice, and finally results in capital impact on thermal stability of the organic material. Thus lowering the high sublimation temperature of such a material is a very important parameter to ensure processability of the material. Further, the problems of lower yield and difficulties in purification during the process for preparing 1-phenylisoquinoline iridium complex should be overcome for common use.

### DISCLOSURE

### Technical Problem

The object of the present invention is to solve the problems described above to overcome the disadvantage of the red phosphors and to provide improved light emitting materials, as well as a process for preparing the same to ensure the yield to the extent of being employed in common use.

### Technical Solution

As a result of intensive researches to solve the problems of prior art, the present inventors found electroluminescent materials comprised of mixtures having excellent light emitting properties, which can be easily prepared with high yield. More specifically, the electroluminescent material according to the present invention is characterized in that it is comprised of a mixture of compound(s) represented by Chemical Formula 1 and compound(s) represented by Chemical Formula 2:

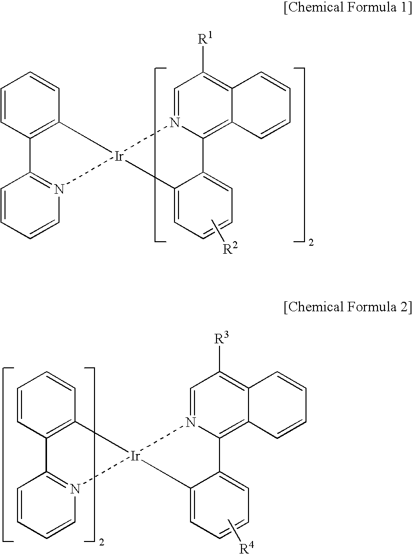

wherein, the groups from R¹ to R⁴ may be same or different from each other, and each group independently represents hydrogen, linear or branched C₁-C₅ alkyl group with or without halogen substituent(s), or halogen.

The electroluminescent material comprised of a mixture according to the present invention, having high light emitting property, can be easily prepared with high yield.

Other and further objects, features and advantages of the invention will appear more fully from the following description.

The electroluminescent material comprised of a mixture according to the present invention preferably comprises a compound represented by Chemical Formula 1 and a compound represented by Chemical Formula 2. In particular, though the groups from R¹ to R⁴ may be same or different from each other, preferable is a mixture prepared in a single stage in the preparation having R¹ and R³ being the same, and R² and R⁴ being the same.

In order to satisfy the properties as a red electroluminescent material, the carbon number of the substituents need not be very large, and the substituents preferably are at the 4-position of the isoquinoline ring and para-position of the phenyl substituted at 1-position of the isoquinoline ring as in Chemical Formulas 3 and 4:

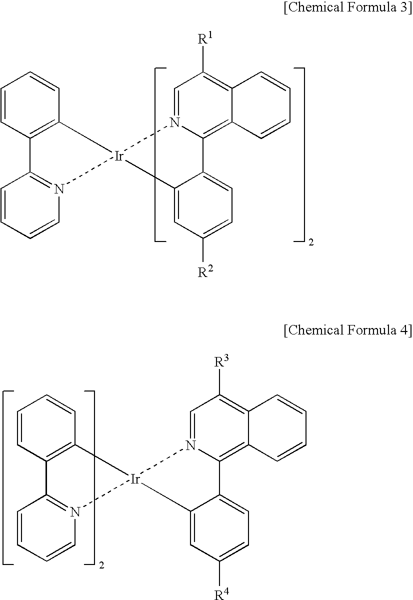

wherein, R¹═R³, R²═R⁴, and R¹ and R₂ independently represent hydrogen, methyl, ethyl or fluorine.

The most preferable material is the mixture comprised of the compound of Chemical 3 and the compound of Chemical Formula 4 wherein each group from R¹ to R⁴ is hydrogen, in view of reproducibility of mixed ratio in the preparing stage, easiness of preparation and the light emitting property.

Preferably, the composition of the electroluminescent material comprised of the mixture according to the present invention is 1˜9 moles of compound represented by Chemical Formula 3 to 9˜1 moles of compound represented by Chemical Formula 4. As considering the reproducibility of composition ratio during the preparation of the mixture and the light emitting property, the most preferable ratio is 3˜5 moles of the compound represented by Chemical Formula 3 to 7˜5 moles of the compound represented by Chemical Formula 4.

The light emitting material comprised of the mixture according to the present invention wherein R¹═R³ and R²═R⁴ can be prepared by applying Reaction Scheme 1 illustrated below:

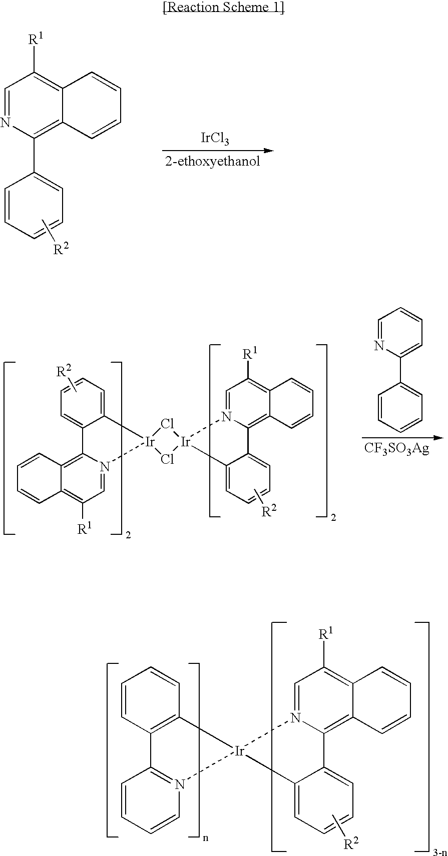

Thus, the light emitting material comprised of the mixture according to the present invention is easily prepared, as illustrated by Reaction Scheme 1, via the steps of

a) reacting a 1-phenylisoquinoline derivative with iridium chloride in the presence of organic solvent to prepare corresponding μ-dichlorodiiridium compound; and

b) reacting the μ-dichlorodiiridium compound prepared from the previous step with a 2-phenylpyridine derivative in the presence of organic solvent at a temperature between 90° C. and 130° C.

Alternatively, μ-dichlorodiiridium may be prepared from a 2-phenylpyridine derivative instead of the 1-phenylisoquinoline derivative as the starting material, which is then reacted with 1-phenylisoquinoline, as illustrated by Reaction Scheme 2:

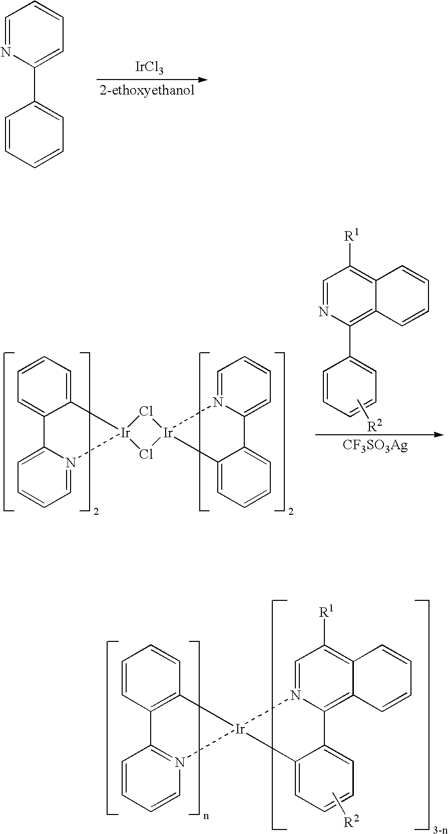

The mixture in case that R¹ is different from R³ and R² is different from R⁴ may be prepared by adding the 1-phenylisoquinoline derivative in an appropriate ratio in step 2.

The μ-dichlorodiiridium compound can be prepared in a high yield by reacting iridium trichloride (IrCl₃) with 2-phenylpyridine or 1-phenylisoquinoline in a molar ratio of 1:2˜3, preferably about 1:2.2 with heating under reflux in the presence of solvent, and isolating the diiridium dimer. The solvent used in the reaction step is a polar solvent, preferably alcohol or a mixed solvent of alcohol/water, such as 2-ethoxyethanol and a mixed solvent of 2-ethoxyethanol/water.

The isolated μ-dichlorodiiridium dimer is reacted with 1-phenylisoquinoline or 2-phenylpyridine as the compound not employed in the preparation of the dimer in the presence of AgCF₃SO₃, Na₂CO₃, NaOH or the like using a solvent such as 2-ethoxyethanol or diglyme at a temperature between 90° C. and 130° C. Extraction of the resultant reaction mixture with organic solvent and recrystallization from an appropriate solvent gives a mixture as the final product in a high yield. The molar ratio of the reactants may be appropriately determined depending upon the desired composition of the mixture.

The production ratio of the compound of Chemical Formula 1 to the compound of Chemical Formula 2 as the final products depends on the ratio of the μ-dichlorodiiridium dimer and 1-phenylisoquinoline or 2-phenylpyridine incorporated as the compounds not employed in preparing the diiridium dimer, and on the temperature. However, if the incorporation ratio of the reactant is identical and a reaction temperature is fixed within the range from 90 to 130° C., the composition of the mixture to be produced has considerable reproducibility.

The 2-phenylpyridine and 1-phenylisoquinoline derivatives according to the present invention are known substances which have been described in previous literature in the art, and the process for preparing the electroluminescent materials comprised of the mixture according to the present invention is not restricted to the processes illustrated by Reaction Scheme 1 or Reaction Scheme 2. In addition, the process according to Reaction Scheme 1 or Reaction Scheme 2 may be adapted, or any preparing process via other route may be carried out. Since the preparation can be performed without difficulty by a person having ordinary skill in the art by using conventional methods of organic synthesis, it is not described here in detail.

### BRIEF DESCRIPTION OF THE DRAWINGS

FIG. 1 is a cross-sectional view of an organic EL device;

FIG. 2 is a graph showing the luminous efficiency property depending on the mixed composition of the electroluminous materials comprised of different mixtures according to the present invention;

FIG. 3 is a graph showing current density versus voltage property depending on the mixed composition of the electroluminous materials comprised of different mixtures according to the present invention;

FIG. 4 is a graph showing luminance versus voltage property depending on the mixed composition of the electroluminous materials comprised of different mixtures according to the present invention;

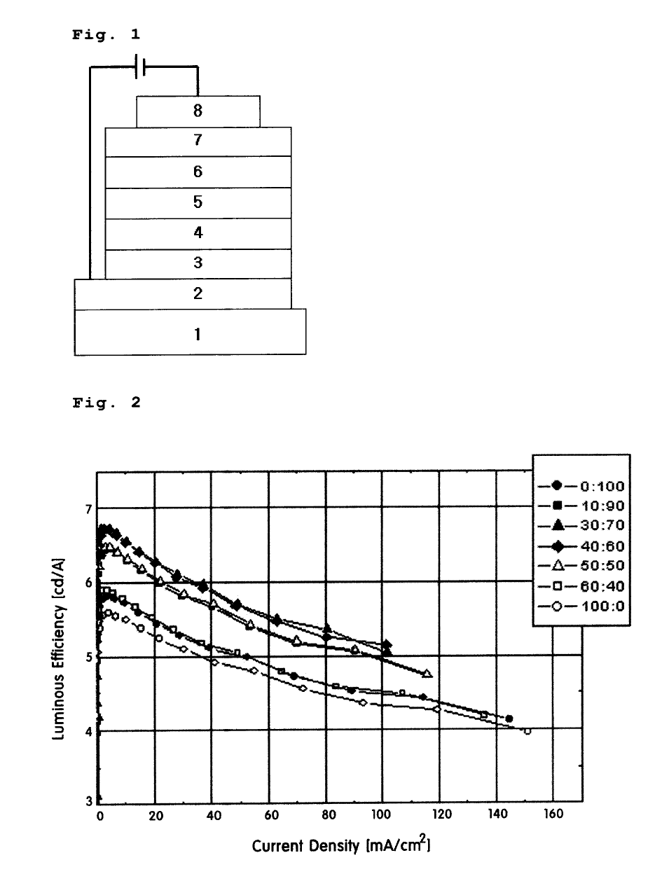

### DESCRIPTION OF SYMBOLS OF SIGNIFICANT PARTS OF THE DRAWINGS

1: a glass for organic EL
2: a transparent electrode ITO thin film
3: a hole transport layer
4: a light emitting layer
5: a hole blocking layer
6: an electron transport layer
7: an electron injecting layer
8: a cathode

### MODE FOR INVENTION

Now, the present invention is described as referring to exemplary processes for preparing the novel electroluminescent compounds according to the present invention by way of Examples. These Examples, however, are intended to provide better understanding of the invention, and it should be understood that the scope of the invention is not restricted thereto.

### EXAMPLES

The compounds used in the Examples are abbreviated as follows:

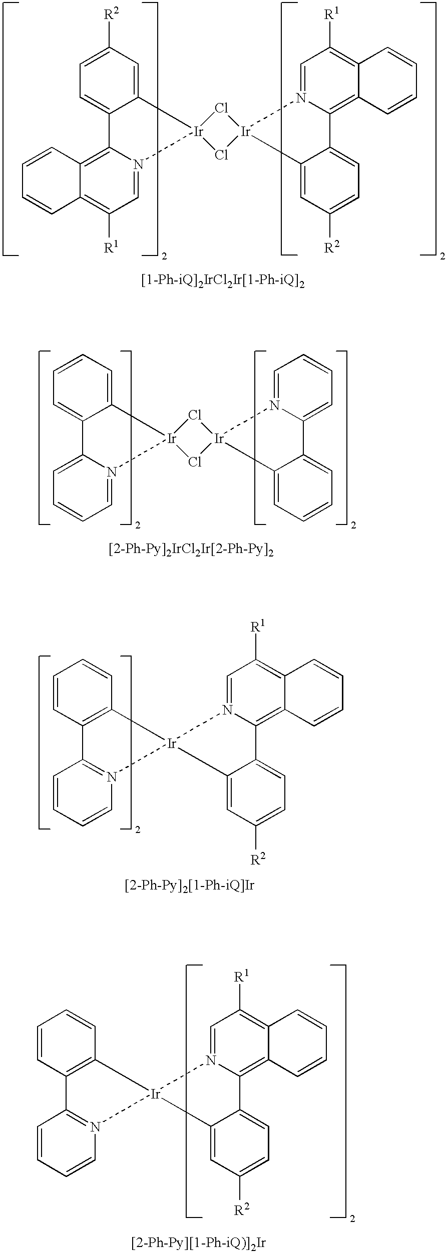

### Example 1

### Preparation of [1-Ph-iQ(R¹═R²═H)]₂IrCl₂Ir[1-Ph-iQ(R¹═R²═H)]₂

Iridium chloride (III) (1.0 g, 3.43 mmol) and 1-phenylisoquinoline (1.6 g, 7.80 mmol) were added to 20 mL of 2-ethoxyethanol, and the resultant mixture was heated under reflux under nitrogen for 16 hours. At ambient temperature, 50 mL of water was added to the reaction mixture, and the solid generated was filtered and washed with cold methanol to obtain the title compound, μ-dichlorodiiridium intermediate (1.42 g, 1.12 mmol, yield: 65%) as red crystal.

### Example 2

### Preparation of [2-Ph-Py]₂IrCl₂Ir[2-Ph-Py]₂

Iridium chloride (III) (1.0 g, 3.43 mmol) and 2-phenyl pyridine (1.17 g, 7.55 mmol) were added to 20 mL of 2-ethoxyethanol, and the resultant mixture was heated under reflux under nitrogen for 16 hours. At ambient temperature, 50 mL of water was poured into the reaction mixture, and the solid generated was filtered and washed with cold methanol to obtain the title compound, μ-dichlorodiiridium intermediate (1.57 g, 1.46 mmol, yield: 85%) as yellow crystal.

### Example 3

### Preparation of [1-Ph-iQ(R¹═CH₃, R²═H)]₂IrCl₂Ir[1-Ph-iQ(R¹═CH₃, R═H)]₂

In a mixed solvent of toluene-ethanol (5:3, 80 mL), dissolved were p-tolyl boronic acid (1.50 g, 11.0 mmol), 1-chloroisoquinoline (1.63 g, 10.0 mmol) and tetrakis(triphenylphosphine)palladium (0) (0.64 g, 0.55 mmol). Thirty (30) mL of 2M aqueous sodium carbonate solution and 1 mL of pyridine were added thereto, and the resultant mixture was heated under reflux for a day. After quenching, the reaction mixture was cooled to ambient temperature, extracted with ethyl acetate, and recrystallized from chloroform to obtain the ligand 1-(p-tolyl)-isoquinoline (1-p-tol-iQ (R¹═CH₃, R²═H) (1.75 g, 8.0 mmol) as white solid.

¹H NMR (200 MHz, CDCl₃): δ 2.3 (s, 3H), 7.05-7.20 (q, 3H), 7.45-7.60 (m, 2H), 7.7-7.9 (q, 4H), 8.4 (d, 1H)

By using iridium chloride (III) (1.06 g, 3.64 mmol) and the ligand (1.75 g, 8.0 mmol) thus prepared, the same procedure as described in Example 1 was repeated to obtain the title compound, μ-dichlorodiiridium intermediate (1.30 g, 0.99 mmol, yield: 54%).

### Example 4

To 10 mL of diglyme, were added μ-dichlorodiiridium complex [1-Ph-iQ]₂IrCl₂Ir[1-Ph-iQ]₂ (1.12 mmol), 2-phenylpyridine (0.38 g, 2.45 mmol) and AgCF₃SO₃ (0.60 g), and the resultant mixture was heated under nitrogen at a temperature between 90° C. and 130° C. for 12 to 48 hours. At ambient temperature, 50 mL of water was poured into the reaction mixture, and the solid generated was filtered, extracted with methylene chloride, and recrystallized from a mixed solvent of methylene chloride and methanol, to obtain [2-Ph-Py]_{2[}1-Ph-iQ]Ir and [2-Ph-Py][1-Ph-iQ]₂Ir in a molar ratio from 1:9 to 9:1 (yield: 10˜40%). The ratio of the mixture prepared was determined by HPLC. ODS column (manufactured by Waters) was employed, and a mixed solvent of methanol and water (9:1) was used as solvent.

The product ratios of [2-Ph-Py]_{2[}1-Ph-iQ]Ir and [2-Ph-Py][1-Ph-iQ]₂Ir dependent on the reaction conditions, and the yields are shown in Table 1.

TABLE 1

| | | | Product ratio of | | |
|---|---|---|---|---|---|
| | Reaction | | [2-Ph-Py]₂[2- | | |
| | Temper- | Reaction | Ph-iQ]Ir and | | |
| | ature | Time | [2-Ph-Py][2-Ph- | | Yield |
| | (° C.) | (hr) | iQ]₂Ir (molar) | Substituent | (%) |
| 1 | 90 | 12 | 50:50 | R¹═R²═H | 10 |
| 2 | 110 | 12 | 60:40 | | 28 |
| 3 | 130 | 12 | 10:90 | | 20 |
| 4 | 90 | 24 | 40:60 | | 13 |
| 5 | 110 | 24 | 65:35 | | 37 |
| 6 | 130 | 24 | 25:75 | | 40 |
| 7 | 90 | 36 | 45:55 | | 15 |
| 8 | 110 | 36 | 55:45 | | 30 |
| 9 | 130 | 36 | 30:70 | | 34 |
| 10 | 90 | 48 | 35:65 | | 16 |
| 11 | 110 | 48 | 40:60 | | 23 |
| 12 | 130 | 48 | 35:65 | | 25 |
| 13 | 110 | 24 | 20:80 | R¹═CH₃, | 25 |
| | | | | R²═H | |

As can be seen from Table 1, though the product ratio of [2-Ph-Py]_{2 [}1-Ph-iQ]Ir versus [2-Ph-Py][1-Ph-iQ]₂Ir showed differences depending upon the reaction temperature and reaction time, such ratio exhibited considerable reproducibility under identical reaction condition. By selecting the ratio and synthetic yield providing the most excellent performance, one can assure mass productivity of materials having high performances.

### Comparative Example 1

### [2-Ph-Py][1-Ph-iQ(R¹═R²═H)]₂Ir

To 10 mL of diglyme, added were μ-dichlorodiiridium complex [1-Ph-iQ(R¹═R²═H)]₂IrCl₂Ir[1-Ph-iQ(R¹═R²═H)]₂ (1.42 g, 1.12 mmol) prepared from Example 1, 2-phenyl pyridine (0.38 g, 2.45 mmol) and AgCF₃SO₃ (0.60 g), and the resultant mixture was heated under nitrogen at 110° C. for 24 hours. At ambient temperature, 50 mL of water was added to the reaction mixture, and the solid generated was filtered, extracted with methylene chloride and purified by column chromatography to obtain the title compound (0.15 g, 0.20 mmol, 9%) in a low yield.

¹H NMR (200 MHz, CDCl₃): δ 6.9-7.1 (m, 3H), 7.2-7.35 (m, 9H), 7.45-7.75 (m, 8H), 7.8-8.05 (m, 5H), 8.4 (m, 2H), 8.5-8.6 (d, 1H)

MS/FAB: 755 (found), 754.90 (calculated)

### Comparative Example 2

### [2-Ph-Py]_{2[}1-Ph-iQ(R¹═R²═H)]Ir

To 15 mL of diglyme, added were μ-dichlorodiiridium complex (1.57 g, 1.46 mmol) prepared from Example 2, 1-phenyl isoquinoline (0.66 g, 3.21 mmol) and AgCF₃SO₃ (1.04 g), and the resultant mixture was heated under nitrogen at 110° C. for 24 hours. At ambient temperature, 50 mL of water was added to the reaction mixture, and the solid generated was filtered, extracted with methylene chloride and purified by column chromatography to obtain the title compound (0.15 g, 0.21 mmol, yield: 7%).

¹H NMR (200 MHz, CDCl₃): δ 6.9-7.1 (m, 3H), 7.25-7.35 (m, 9H), 7.45-7.7 (m, 7H), 7.9-8.05 (m, 4H), 8.4 (d, 1H), 8.5-8.6 (m, 2H)

MS/FAB: 705 (found), 704.84 (calculated)

As can be seen from Example 3 and Comparative Examples 1 and 2, the electroluminescent material comprised of a mixture according to the present invention has high yield to the extent to be commonly used after performing simple purification process, while the electroluminescent comprising a single compound has low yield to be utilized in common use and needs very complicated purification processes.

### Example 5

### Manufacture of OLED

OLED devices were manufactured by using the light emitting material prepared from Example 4 as a light emitting dopant.

A transparent electrode ITO thin film (15Ω/□) obtained from glass for OLED (manufactured from Samsung-Corning) was subjected to ultrasonic washing sequentially with trichloroethylene, acetone, ethanol and distilled water, and stored in isopropanol.

Then, an ITO substrate is equipped on a substrate folder of a vacuum vapor deposition device, and 4,4′,4″-tris(N,N-(2-naphthyl)-phenylamino)triphenylamine (2-TNATA) was charged in a cell of the vacuum vapor deposition device. After ventilation to reach the degree of vacuum in the chamber of 10⁻⁶ torr, electric current was applied to the cell to evaporate 2-TNATA to vapor-deposit a hole injecting layer on the ITO substrate with 60 nm of thickness.

Then, N,N′-bis(α-naphthyl)-N,N′-diphenyl-4,4′-diamine (NPB) was charged in another cell of said vacuum vapor deposition device, and electric current was applied to the cell to evaporate NPB to vapor-deposit a hole transport layer with 20 nm of thickness on the hole injecting layer.

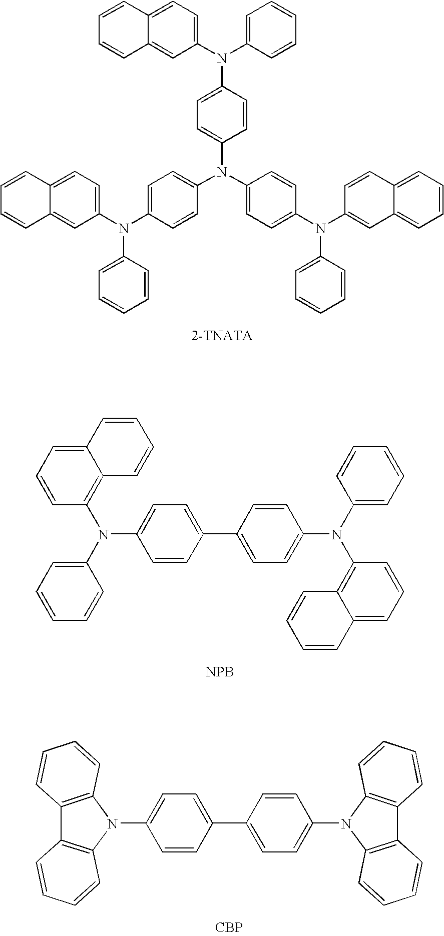

Further, 4,4′-N,N′-dicarbazole-biphenyl (CBP) as a light emitting host material was charged in another cell of the vacuum vapor deposition device, while each light emitting material prepared according to Examples 1 and 2 in still another cell. The two substances were doped by evaporating them in different rates, to vapor-deposit a light emitting layer having 30 nm of thickness on the hole transport layer. The doping concentration of 4 to 10 mol % was appropriate on the basis of CBP.

Then, in the same manner as in the case of NPB, bis(2-methyl-8-quinolinato)(p-phenylphenolato)aluminum (III) (BAlq) as a hole blocking layer was vapor-deposited with a thickness of 10 nm on the light emitting layer, and subsequently tris(8-hydroxyquinoline)aluminum (III) (Alq) as an electron transport layer was vapor-deposited with a thickness of 20 nm. Lithium quinolate (Liq) as an electron injecting layer was then vapor-deposited with a thickness of 1 to 2 nm, and Al cathode was vapor deposited with a thickness of 150 nm by using another vapor deposition device, to manufacture an OLED.

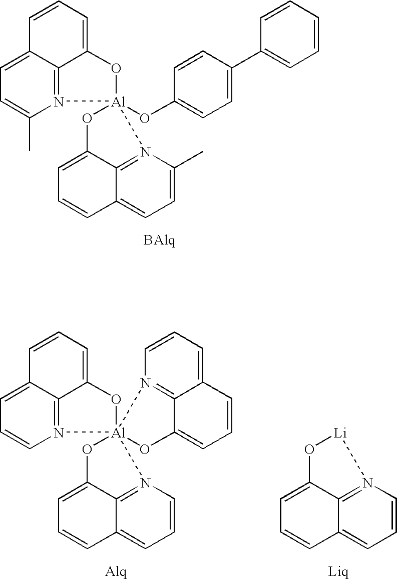

### Example 6

### Evaluation of Optical Properties of Electroluminescent Materials

The complexes having high synthetic yield among the substances were purified by vacuum sublimation under 10⁻⁶ torr, and used as a dopant of an OLED light emitting layer, and luminous efficiencies of the OLEDs were measured at 10 mA/cm².

The light emitting properties of the mixed light emitting material comprised of [2-Ph-Py]_{2[}1-Ph-iQ(R¹═R²═H)]Ir and [2-Ph-Py][1-Ph-iQ(R¹═R²═H)]₂Ir prepared from Example 4 depending on the mixed ratio are comparatively shown in Table 2:

TABLE 2

| | Mixed ratio of | Luminous | |
|---|---|---|---|
| | [2-Ph-Py]₂[2-Ph-iQ(R¹═R²═H)]Ir vs. | efficiency | |
| | [2-Ph-Py][2-Ph-iQ(R¹═R²═H)]₂Ir | (cd/A) | CIE Coordinate |
| 1 | 0:100 | 5.71 | (0.665, 0.332) |
| 2 | 10:90 | 6.25 | (0.667, 0.330) |
| 3 | 30:70 | 6.55 | (0.667, 0.331) |
| 4 | 40:60 | 6.50 | (0.663, 0.335) |
| 5 | 50:50 | 6.32 | (0.664, 0.334) |
| 6 | 60:40 | 5.77 | (0.670, 0.327) |
| 7 | 100:0 | 5.50 | (0.669, 0.328) |

As can be seen from Table 2, the composition ratio did not significantly affect the CIE coordinate but only affect the luminous efficiency. The results come from the fact both [2-Ph-Py]₂[1-Ph-iQ(R¹═R²═H)]Ir and [2-Ph-Py][1-Ph-iQ(R¹═R²═H)]₂Ir are excellent red light emitting materials having pure red color. The prominent light emitting property exhibited as being mixed can be interpreted that these compounds form a thin film system which can constitute appropriate energy transport mechanism when the two compounds are mixed.

Each device employing the mixture as a light emitting dopant has excellent lifespan of 10,000 hours or more. Thus, it is expected that an OLED panel having best light emitting property can be prepared by using an appropriate mixed ratio according to the present invention.

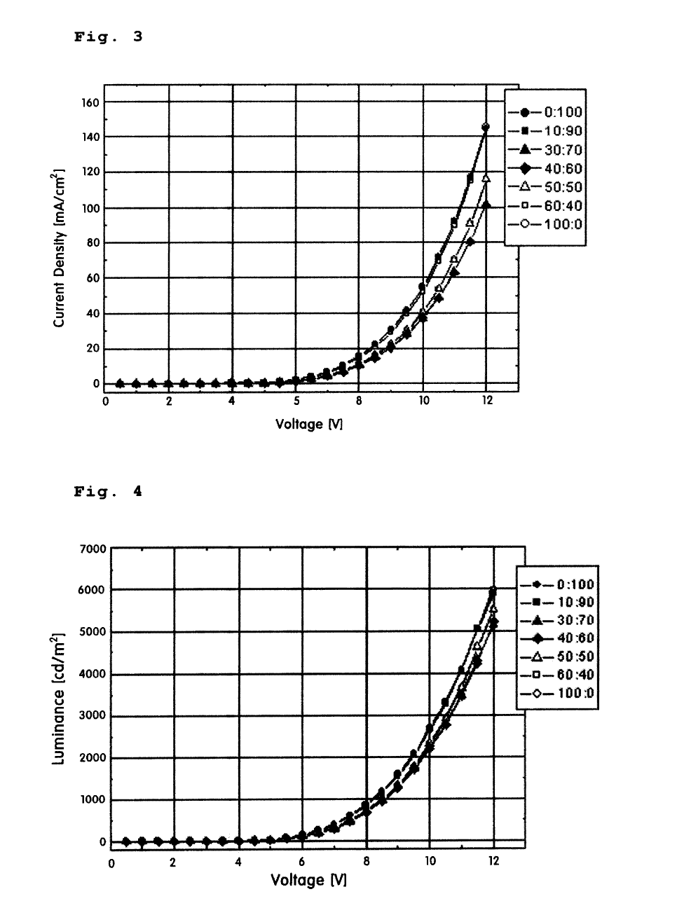

FIG. 2 is a graph showing the luminous efficiency property depending on the mixed ratio of the electroluminescent material comprised of the mixture according to the present invention. FIG. 2 shows the graph of current density—voltage property depending upon the mixed ratio of the electroluminescent material comprised of the mixture according to the present invention, and FIG. 3 shows the graph of luminance—voltage property depending upon the mixed ratio of the electroluminescent material comprised of the mixture according to the present invention.

As can be seen from FIG. 2, when the ratio of [2-Ph-Py]_{2[}1-Ph-iQ(R¹═R²═H)]Ir to [2-Ph-Py][1-Ph-iQ(R¹═R²═H)]₂Ir is maintained within the range from 50:50 to 30:70, it is expected that iridium complex compounds having novel 1-phenylisoquinoline as a ligand with remarkably improved performance as compared to conventional materials can be used as a light emitting material for common use. The vapor deposition temperature of the iridium complex according to the present invention in the OLED vapor deposition device was 270° C., which is far lower than the temperature (330° C.) of 1-phenylisoquinoline iridium complex (tris form). Such lowering of the sublimation temperature of the material can serve as an important factor to secure the processibility and stability of the material.

### INDUSTRIAL APPLICABILITY

As described above, the electroluminescent material comprised of the mixture according to the present invention has excellent lifespan and red light emitting property, and is advantageous for common use as it can be prepared with high production yield, simple purification process and high reproducibility.

1. An electroluminescent material comprised of a mixture of a compound represented by Chemical Formula 1 and a compound represented by Chemical Formula 2: 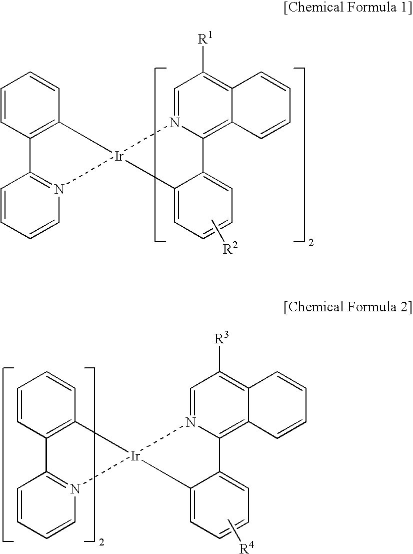
wherein, the groups from R¹ to R⁴ may be same or different from each other, and each group independently represents hydrogen, linear or branched C₁-C₅ alkyl group with or without halogen substituent(s), or halogen.

2. An electroluminescent material according to claim 1, which is comprised of a mixture of a compound represented by Chemical Formula 3 and a compound represented by Chemical Formula 4; 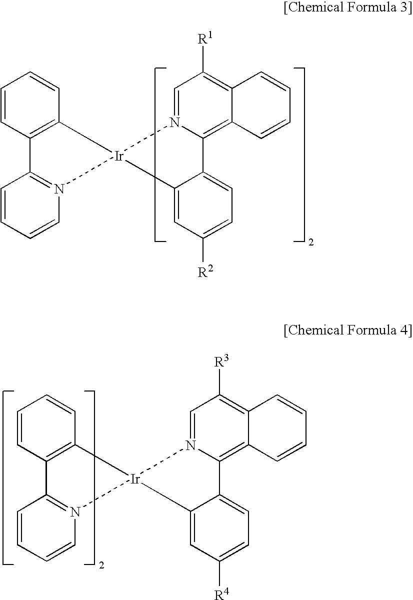
wherein, R¹═R3, R2=R4, and R1 and R2 independently represent hydrogen, methyl, ethyl or fluorine.

3. An electroluminescent material according to claim 2, comprised of a mixture of a compound represented by Chemical Formula 3 and a compound represented by Chemical Formula 4, wherein each substituent from R1 to R4 represents hydrogen.

4. An electroluminescent material according to any claim 1, which is comprised of a mixture having the ratio of 1˜9 mole(s) of the compound of Chemical Formula 3 to 9˜1 mole(s) of the compound of Chemical Formula 4.

5. An electroluminescent material according to claim 4, which is comprised of a mixture having the ratio of 3˜5 mole(s) of the compound of Chemical Formula 3 to 7˜5 mole(s) of the compound of Chemical Formula 4.

6. A process for preparing an electroluminescent material comprised of a mixture of a compound of Chemical Formula 1 and a compound of Chemical Formula 2 according to claim 1, which comprises the steps of
(a) reacting a 2-phenylisoquinoline derivative or 2-phenylpyridine derivative with iridium chloride in the presence of organic solvent as illustrated by Reaction Scheme 1 or Reaction Scheme 2 to prepare corresponding μ-dichlorodiiridium compound; and
(b) reacting the μ-dichlorodiiridium compound prepared from the previous step with 2-phenylpyridine derivative or 2-phenylisoquinoline derivative which did not participated in the reaction of step a) in the presence of organic solvent at a temperature between 90° C. and 130° C.

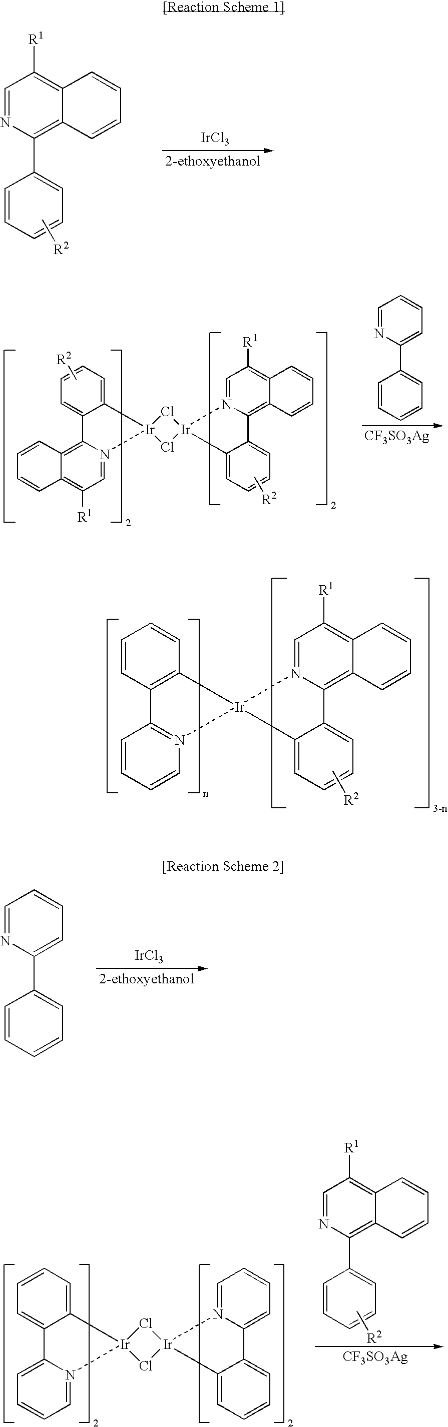

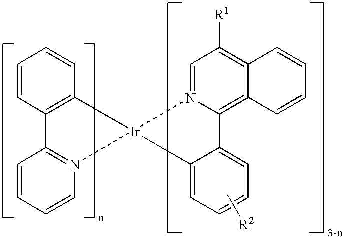

7. A display device comprising an electroluminescent material comprised of the mixture according to claim 1.

8. An electroluminescent material according to claim 2, which is comprised of a mixture having the ratio of 1˜9 mole(s) of the compound of Chemical Formula 3 to 9˜1 mole(s) of the compound of Chemical Formula 4.

9. An electroluminescent material according to claim 3, which is comprised of a mixture having the ratio of 1˜9 mole(s) of the compound of Chemical Formula 3 to 9˜1 mole(s) of the compound of Chemical Formula 4.

10. A display device comprising an electroluminescent material comprised of the mixture according to claim 2.

11. A display device comprising an electroluminescent material comprised of the mixture according to claim 3.

12. A display device comprising an electroluminescent material comprised of the mixture according to claim 4.

13. A display device comprising an electroluminescent material comprised of the mixture according to claim 5.

14. A display device comprising an electroluminescent material comprised of the mixture according to claim 8.

15. A display device comprising an electroluminescent material comprised of the mixture according to claim 9.
